(19) United States
(12) Patent Application Publication
(10) Pub. No.: US 2026/0229440 A1
(43) Pub. Date: Aug. 6, 2026

(54) Insulator, Charged Particle Gun, and Charged Particle Beam Device

(71) Applicant: Hitachi High-Tech Corporation, Minato-ku, Tokyo (JP)

(72) Inventors: Shuhei ISHIKAWA, Tokyo (JP); Hiroshi MORITA, Tokyo (JP); Daigo KOMESU, Tokyo (JP); Takashi DOI, Tokyo (JP); Tatsuya MIYAKE, Tokyo (JP); Soichi KATAGIRI, Tsukuba-shi (JP); Yasushi YAMANO, Tsukuba-shi (JP); Takashi NAITO, Tokyo (JP)

(21) Appl. No.: 19/149,577

(22) PCT Filed: Feb. 24, 2023
(86) PCT No.: PCT/JP2023/006644

§ 371 Date: Jul. 21, 2025

(51) Int. Cl. H01J 29/06

(52) U.S. Cl. CPC H01J 29/06

(57) ABSTRACT

An object of the disclosure is to provide an insulator capable of shortening a conditioning time and reducing a withstand voltage failure when a voltage difference between electrodes is about several 10 kV. The insulator according to the disclosure includes an insulating material portion and a glass film, and a boundary between the insulating material portion and an end portion of a cathode on a side facing an anode is covered with the glass film

### TECHNICAL FIELD

The present disclosure relates to an insulator disposed between electrodes in a vacuum chamber.

### BACKGROUND ART

An electron beam or an ion beam used in an electron beam accelerator or the like provided in an electron microscope, an ion beam processing device, a radiation facility, or the like is emitted from a slightly pointed tip of an electron source or an ion source by concentrating an electric field on the pointed tip in a vacuum. In order to implement this, a plurality of electrodes having different voltages are fixed in the vicinity of the electron source and the ion source via insulators. A voltage difference between the electrodes is often several 100 V to several 10 kV. In order to stably maintain such a voltage difference without discharging, a conditioning process is required when an electron gun or an ion gun is started.

In the conditioning process, surface flashover discharge is generated by concentrating an electric field on a tip end of a minute protrusion portion formed on a surface of the electrode, and accordingly, the protrusion portion is repeatedly eliminated by Joule heat. Accordingly, the number of protrusion portions on which the electric field concentrates is reduced, so that a voltage that can be applied between the electrodes can be increased without causing the surface flashover discharge.

Since the conditioning process leads to an increase in labor and manufacturing time required in a start-up process of the electron gun or the ion gun, it is a problem to shorten a process time. Further, there is also a problem that the conditioning process is not normally completed, a predetermined withstand voltage is not obtained, and the product is discarded as a defective product, and the yield is reduced.

PTL 1 discloses, as a method for preventing surface flashover discharge, a method for preventing surface flashover discharge by applying vanadium-containing glass, which is metallic glass exhibiting semi-conductivity, to the entire surface of an insulator to prevent charge-up. It is also described that the vanadium-containing glass surface has a vacuum evacuation function for gas adsorption.

### CITATION LIST

### Patent Literature

PTL 1: US2018/0019096

### SUMMARY OF INVENTION

### Technical Problem

A resistivity of the vanadium-containing glass described in PTL 1 is 10⁶ to 10¹³ Ω·cm. This resistivity correlates with a film thickness, and corresponds to about several 10 μm to 1 nm. For example, in order to maintain a voltage difference between electrodes of several 10 kV, the film thickness of the metallic glass needs to be thinner than at least 1 μm. However, since a height of unevenness of a cathode edge is in the degree of um, when the film thickness of the metallic glass is 1 μm or less, an uneven shape remains as it is. Then, even when the conditioning process is performed, there is a problem that the electric field is inevitably concentrated on the protrusion portion of the electrode surface, and surface flashover discharge is caused.

The disclosure has been made in view of the above problems, and an object of the disclosure is to provide an insulator capable of shortening a conditioning time and reducing a withstand voltage failure when a voltage difference between electrodes is about several 10 kV.

### Solution to Problem

The insulator according to the disclosure includes an insulating material portion and a glass film, and a boundary between the insulating material portion and an end portion of a cathode on a side facing an anode is covered with the glass film.

### Advantageous Effects of Invention

According to an insulator of the disclosure, when a voltage difference between electrodes is about several 10 kV, a conditioning period can be significantly shortened, and a withstand voltage failure can be reduced.

### BRIEF DESCRIPTION OF DRAWINGS

FIG. 1 is a schematic view illustrating a physical phenomenon in a conditioning process of an insulator.

FIG. 2 is a side view illustrating a structure of the insulator according to Embodiment 1.

FIG. 3 illustrates a model for numerically calculating an electric field intensity distribution when a voltage of −10 kV is applied to a cathode 2 having the structure illustrated in FIG. 2.

FIG. 4 illustrates a calculation result using the model of FIG. 3.

FIG. 5 is an enlarged schematic view of an actual electrode surface.

FIG. 6 is an enlarged schematic view of the insulator according to Embodiment 1.

FIG. 7 is an enlarged schematic view of the insulator described in PTL 1.

FIG. 8 illustrates a configuration example in which an alumina insulator 1 according to Embodiment 1 is applied to a current introduction terminal of an electron gun.

FIG. 9 illustrates a member in which the cylindrical alumina insulator 1 and a ring-shaped metal part 10 are bonded and fixed by a metallization film 8.

FIG. 10 illustrates a configuration example in which the alumina insulator 1 according to Embodiment 1 is applied to a scanning electron microscope (SEM).

### DESCRIPTION OF EMBODIMENTS

### Conditioning Process

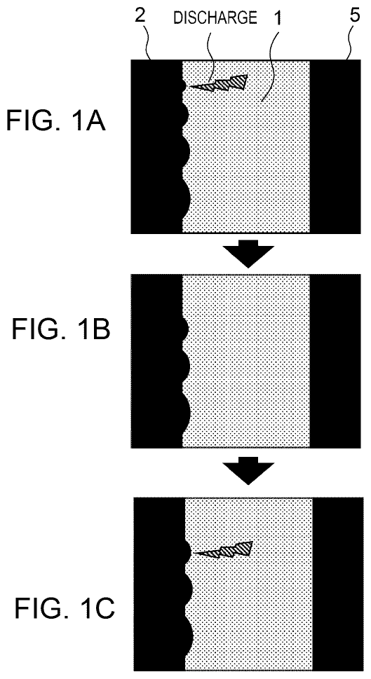

FIG. 1 is a schematic view illustrating a physical phenomenon in a conditioning process of an insulator. In order to facilitate understanding of the disclosure, an outline of the conditioning process will be described with reference to FIG. 1 before describing an embodiment of the disclosure.

Discharge in a section in which a cathode 2 and an anode 5 are fixed with an alumina insulator 1 interposed therebetween is referred to as surface flashover discharge. In a general design, a distance between the cathode and the anode is secured in order to reduce an electric field intensity so as not to cause the surface flashover discharge. However, unevenness in the degree of um is formed on an actual cathode end surface (an end portion surface on a side where the cathode 2 faces the anode 5), and the shape thereof also varies. When a negative voltage is gradually applied to the cathode 2 in this state, an electric field is concentrated on the sharpest protrusion portion to generate field emission electrons, thereby causing surface flashover discharge (I). At this time, the pointed tip end is dissolved and eliminated by Joule heat (II). When the cathode 2 is energized again and the voltage is gradually increased, the electric field is concentrated on the pointed protrusion portion, and surface flashover discharge occurs (III). When this operation is repeated, since the voltage applied to the cathode 2 increases, this operation is continued until the voltage becomes equal to or higher than a predetermined voltage. The above processing is called conditioning.

### Embodiment 1

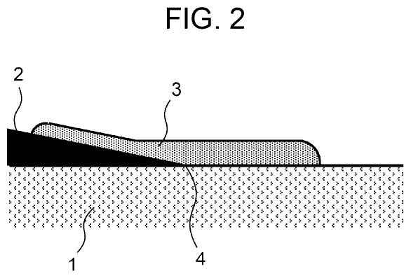

FIG. 2 is a side view illustrating a structure of an insulator according to Embodiment 1 of the disclosure. The insulator according to the embodiment is assumed to be disposed between the cathode 2 and the anode 5 in a vacuum chamber, and is formed of the alumina insulator 1 and a low-melting point metallic glass 3. When a negative voltage is applied to the cathode 2 formed on a surface of the alumina insulator 1 (insulating material portion) placed in vacuum, an electric field is concentrated on a triple point 4, which is an edge of the cathode 2, and field emission electrons are emitted, resulting in surface flashover discharge. In the structure of FIG. 2, the electric field concentration applied to the triple point 4 is relaxed by covering the triple point 4 with the low-melting point metallic glass 3. An example in which vanadium-containing glass is used as the low-melting point metallic glass 3 will be described below.

Alumina is often used as the insulating material portion (insulator body indicated by reference numeral 1 in FIG. 2). A surface roughness of the alumina insulator 1 is about 20 μm. Many of the cathodes 2 are formed by plating a metallization film of molybdenum or manganese with nickel. The low-melting point metallic glass 3 extends along a depth direction in FIG. 2 (a longitudinal direction in FIG. 1).

The low-melting point metallic glass 3 covers the triple point 4 and the periphery thereof. The triple point 4 is a boundary between the alumina insulator 1 and an end portion of the cathode 2 on a side facing the anode 5. Therefore, the low-melting point metallic glass 3 covers a range from (a) an upper surface of the cathode 2 to (c) a position of a region between the cathode 2 and the anode 5 through (b) the boundary (triple point 4) between the end portion surface of the cathode 2 and the alumina insulator 1. However, the low-melting point metallic glass 3 is disposed not to electrically connect the cathode 2 and the anode 5 (that is, the low-melting point metallic glass 3 does not extend to the anode 5).

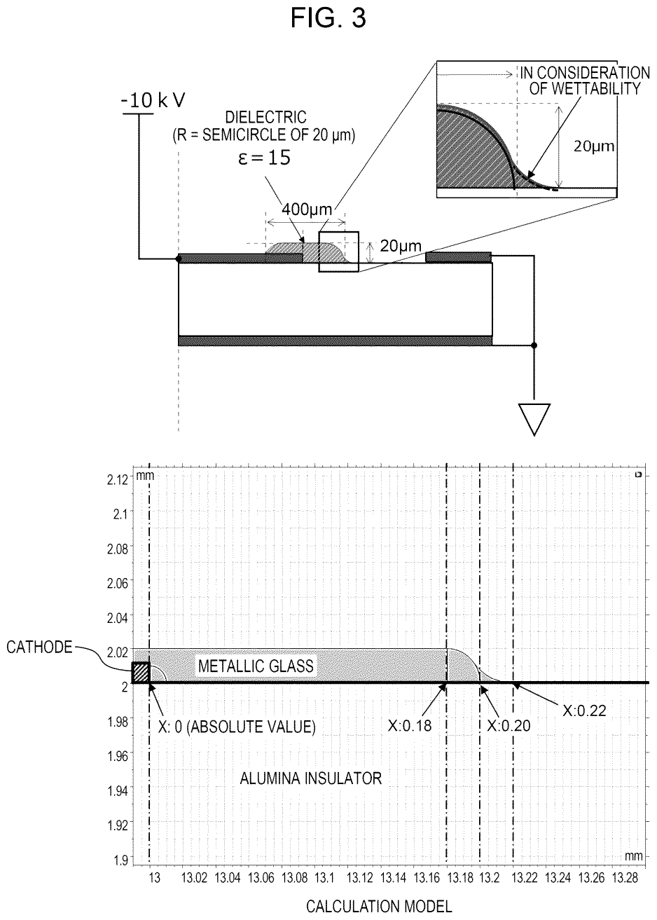

FIG. 3 illustrates a model for numerically calculating an electric field intensity distribution when a voltage of −10 kV is applied to the cathode 2 having the structure illustrated in FIG. 2. A relative permittivity of the alumina insulator 1 is 10, and a relative permittivity of the vanadium-containing glass is 15. The vanadium-containing glass (low-melting point metallic glass 3) has a width of 400 μm so as to cover the cathode 2 and the alumina insulator (alumina insulator 1), and has a film thickness of 20 μm.

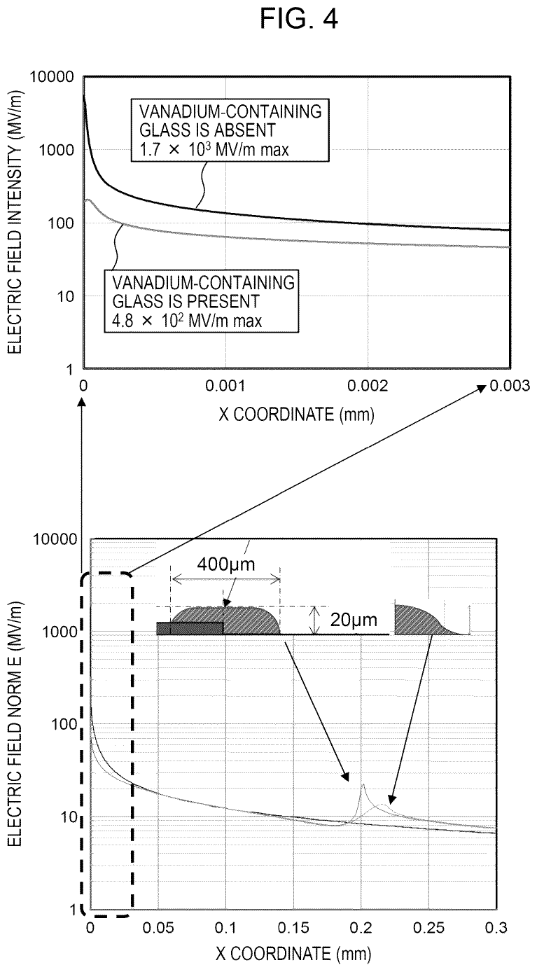

FIG. 4 illustrates a calculation result using the model of FIG. 3. As illustrated in the upper part of FIG. 4, when there is no vanadium-containing glass, an electric field concentrates on a cathode edge, and a strong electric field of 1.7×10³ MV/m is generated. In contrast, when the vanadium-containing glass is applied, the electric field at the cathode edge is reduced to 4.8×10² MV/m.

The lower part of FIG. 4 illustrates the calculation result in consideration of wettability of the vanadium-containing glass at the end portion. The boundary (a peak near x=0.2 in the lower part of FIG. 4) between the alumina insulator 1 and the end portion of the vanadium-containing glass (low-melting point metallic glass 3) on the side of the anode 5 tends to be a secondary triple point at which the electric field concentrates. However, it can be seen that the electric field is significantly smaller than the electric field at the cathode edge (x=0) when the vanadium-containing glass is not present.

An arrow on the right side in the lower part of FIG. 4 indicates an electric field at an edge portion (near x=0.2) of the low-melting point metallic glass 3 when the wettability of the low-melting point metallic glass 3 is good. As illustrated in the graph, it can be seen that when the wettability of the low-melting point metallic glass is good, the electric field near the edge portion can be further reduced.

The result of FIG. 4 can be understood as follows. A surface shape of the low-melting point metallic glass 3 on the side facing the anode 5 is smoother than a surface shape of the cathode 2. That is, a radius of curvature of a surface shape of the low-melting point metallic glass 3 is larger than a radius of curvature of a protrusion portion formed on the surface of the cathode 2. Accordingly, the electric field is less likely to concentrate on a surface of the end portion of the low-melting point metallic glass 3 on the side of the anode 5, resulting in the result illustrated in the upper part of FIG. 4. Further, when the wettability of the low-melting point metallic glass 3 is good, the surface shape becomes smoother, so that the electric field is less likely to be further concentrated, and a result indicated by two arrows in the lower part of FIG. 4 is obtained. The wettability may be such that at least a contact angle of the low-melting point metallic glass 3 with respect to the alumina insulator 1 is less than 90°.

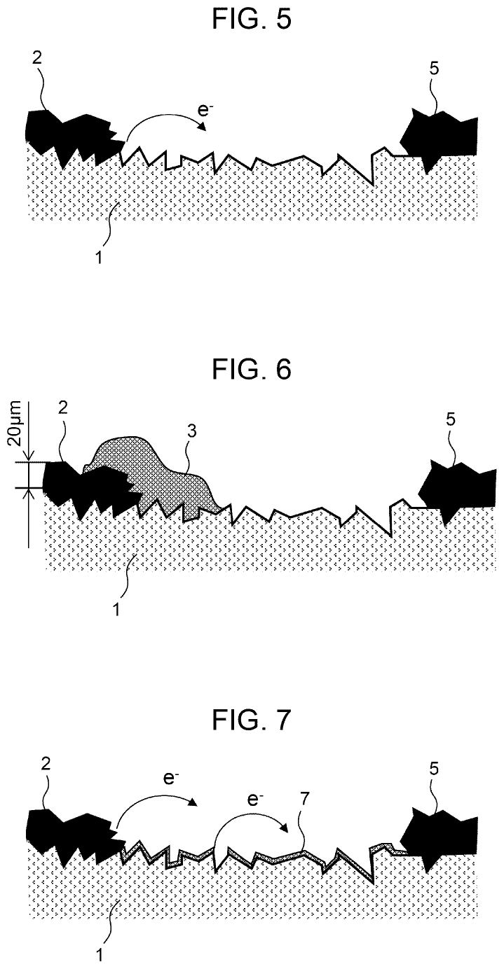

FIG. 5 is an enlarged schematic view of an actual electrode surface. Calculation results described with reference to FIGS. 3 and 4 are numerical estimation based on a simplified shape. However, the unevenness as illustrated in FIG. 5 is formed on an actual cathode end surface. The unevenness is an uneven shape corresponding to a surface roughness of alumina and a grain size of cathode metal. Since a size of the unevenness varies randomly, it is difficult to specify a local position where an electric field concentrates when a voltage is applied to the cathode 2 before discharge. Therefore, field emission electrons are emitted from a place where the electric field concentration is the strongest, leading to surface flashover discharge. Therefore, at the time of start-up in manufacturing an electron gun, a conditioning process is performed in order to secure a withstand voltage characteristic.

FIG. 6 is an enlarged schematic view of the insulator according to Embodiment 1. In the embodiment, as illustrated in FIG. 6, the low-melting point metallic glass 3 is formed to have a thickness of about 20 μm along the edge of the cathode 2. With such a film thickness, the entire vicinity of the triple point can be covered without being affected by the unevenness of the surface of the cathode 2 and the unevenness of the surface of the alumina insulator 1. When heated to a softening temperature, the vanadium-containing glass, which is metallic glass, softens in an amorphous state, and therefore, the vanadium-containing glass adsorbs following the uneven shape and has a smooth surface, and when returned to a room temperature, the vanadium-containing glass solidifies in the amorphous state. Since a resistivity of the vanadium-containing glass having a film thickness of 20 μm is about 10⁶ Ω·cm, the voltage of the low-melting point metallic glass 3 is substantially the same as the voltage of the cathode 2. Accordingly, the electric field concentration at the cathode edge can be nullified, a smooth vanadium-containing glass edge can be obtained, and the overall electric field concentration can be relaxed. Therefore, it is possible to obtain an effect of reducing labor and time of the conditioning process.

The thickness of the low-melting point metallic glass 3 is preferably at least larger than a maximum height of the protrusion portion formed on the surface of the cathode 2 (a maximum peak height on the surface of the cathode 2 on the side facing the anode 5). More desirably, it is considered that when a portion of the low-melting point metallic glass 3 covering the cathode 2 is thicker than a maximum thickness of a portion of the cathode 2 covered with the low-melting point metallic glass 3, the protrusion portion on the surface of the cathode 2 can be completely covered. When a standard film thickness of the cathode 2 is about 20 μm, the film thickness of the low-melting point metallic glass 3 may also be 20 μm.

FIG. 7 is an enlarged schematic view of the insulator described in PTL 1. Metallic glass 7 (vanadium-containing glass) in the related art is formed to cover the entire section between the cathode 2 and the anode 5. Since a voltage of minus several 10 kV or more is applied to the cathode 2, the substantial film thickness is 1 μm or less because the resistivity needs to be about 10¹⁰ Ω·cm. Accordingly, charge-up of the alumina insulator 1 can be eliminated, but it is difficult to eliminate the unevenness of the alumina insulator 1 of 20 μm or more. Then, when a defect is generated in the film of the metallic glass 7 in the related art, there is a problem that the electric field is concentrated thereon and field emission electrons are generated. Further, since minute projections of about several um formed on the cathode 2 having a film thickness of about 20 μm are exposed, it is difficult to reduce field emission electrons. According to the embodiment, such field emission electrons can also be reduced.

### Embodiment 1: Summary

The insulator according to Embodiment 1 includes the alumina insulator 1 and the low-melting point metallic glass 3. The low-melting point metallic glass 3 covers the boundary (triple point 4) between the alumina insulator 1 and the end portion of the cathode 2 on the side facing the anode 5. Accordingly, it is possible to prevent the concentration of the electric field on the protrusion portion formed on the end portion surface of the cathode 2, and to shorten the conditioning process.

### Embodiment 2

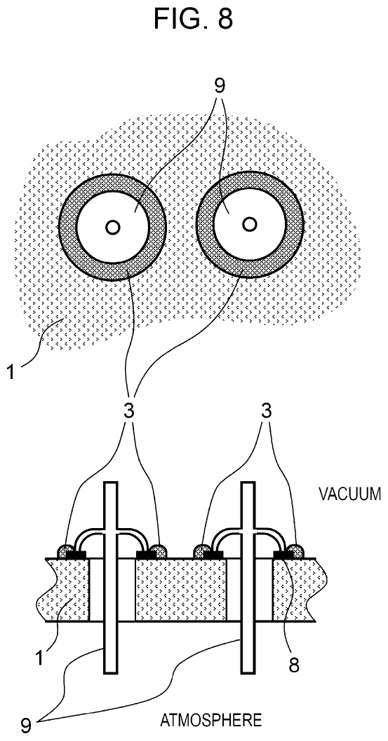

FIG. 8 illustrates a configuration example in which the alumina insulator 1 according to Embodiment 1 is applied to a current introduction terminal of an electron gun. A pin 9 is for supplying a voltage or a current from the atmosphere side into the vacuum. For vacuum sealing, the alumina insulator 1 and the pin 9 are bonded and fixed by a metallization film 8. Since the metallization film 8 is conductive metal, there is a risk of surface flashover discharge when there are a plurality of pins 9. Therefore, a low-melting point metallic glass 6 (vanadium-containing glass) of the disclosure is applied so as to cover the vicinity of an end portion of the metallization film 8. Although there is a voltage difference of several kV between the pins 9 in FIG. 8, the risk of the surface flashover discharge is significantly reduced by adopting such a structure. Therefore, a conditioning process time can be shortened.

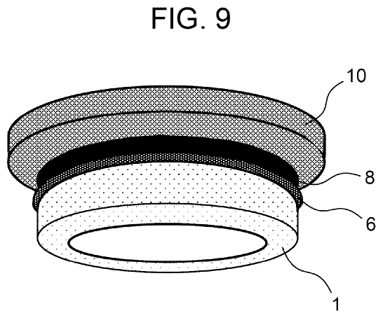

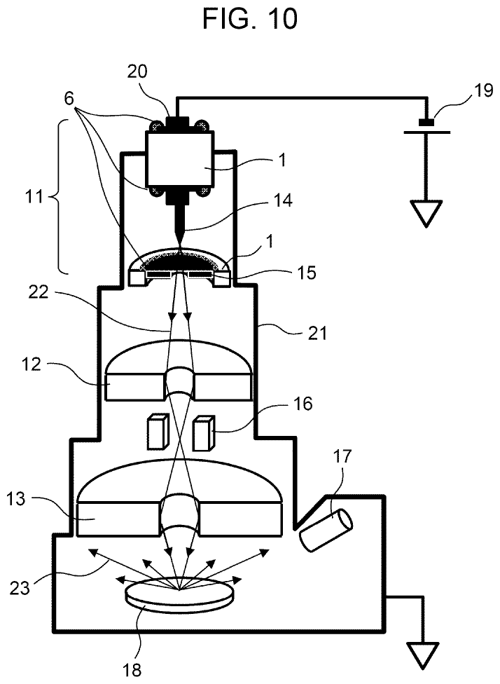

FIG. 9 illustrates a member in which the cylindrical alumina insulator 1 and a ring-shaped metal part 10 are bonded and fixed by the metallization film 8. This member can be applied to a part having a dimension larger than the pin 9 described in FIG. 8.

### Embodiment 3

FIG. 10 illustrates a configuration example in which the alumina insulator 1 according to Embodiment 1 is applied to a scanning electron microscope (SEM). An electron source 14 is disposed at the top of a device, and a voltage is applied from a power supply 19 via a feedthrough 20. The pin 9 described in Embodiment 2 is used for the feedthrough 20, and the low-melting point metallic glass 3 is applied so as to cover the metallization film 8 and the alumina insulator 1. An extraction electrode 15 for extracting electrons is provided in the vicinity of the electron source 14. The extraction electrode 15 is fixed to a column 21 via the alumina insulator 1. Since the column 21 is grounded, the extraction electrode 15 serves as a cathode and the column 21 serves as an anode. Therefore, the low-melting point metallic glass 3 is applied so as to cover an edge of the extraction electrode 15 and the metallization film for bonding and fixing the extraction electrode 15 to the alumina insulator 1. A member from the power supply 19 to the extraction electrode 15 operates as an electron gun 11.

An electron beam 22 extracted from the electron source 14 is focused by a condenser lens 12 and an objective lens 13 to irradiate a sample 18. Secondary electrons 23 generated when the electron beam 22 is deflected by a deflector 16 on the sample 18 to perform raster scanning are detected by a secondary electron detector 17. Accordingly, an enlarged image of the sample 18 can be obtained.

### Regarding Modification of Disclosure

In the above embodiments, the insulator according to the disclosure is disposed between the cathode 2 and the anode 5. When the insulator according to the disclosure is used, the cathode 2 may have a voltage lower than that of the anode 5, and may not necessarily have a negative voltage.

In the above embodiments, an example in which the insulator according to the disclosure is applied to the electron gun or the scanning electron microscope has been described, and the insulator according to the disclosure can also be applied to other charged particle guns or charged particle beam devices.

In the above embodiments, vanadium-containing glass is given as an example of the low-melting point metallic glass 3. The vanadium-containing glass is an example of a semi-conductive glass or a semi-conductive low-melting point metallic glass, and is formed of a metal oxide (including vanadium, tungsten, and the like), but other chalcogenide (including arsenic, antimony, bismuth, and the like) glass can also be used as the low-melting point metallic glass 3.

### REFERENCE SIGNS LIST

1: alumina insulator
2: cathode
3: low-melting point metallic glass
4: triple point
5: anode
7: metallic glass
8: metallization film
9: pin
10: metal part
11: electron gun
12: condenser lens
13: objective lens
14: electron source
15: extraction electrode
16: deflector
17: secondary electron detector
18: sample
19: power supply
20: feedthrough
21: column
22: electron beam
23: secondary electron

1.-13. (canceled)

14. An insulator disposed between a cathode and an anode with respect to the cathode in a vacuum container, the insulator comprising:
an insulating material portion disposed below each of the cathode and the anode; and
a glass film disposed to cover a boundary between the insulating material portion and an end portion of the cathode on a side facing the anode, wherein
the glass film is made of a material containing at least one of semi-conductive glass or semi-conductive low-melting point metallic glass,
a region not covered with the glass film is disposed between the cathode and the anode,
a thickness of the glass film is larger than a maximum peak height of the cathode,
a radius of curvature of a shape of the glass film in the end portion is larger than a radius of curvature of a protrusion portion formed by a surface roughness of the cathode in the end portion.

15. The insulator according to claim 14, wherein
the glass film is disposed to cover a triple point generated at the end portion.

16. The insulator according to claim 14, wherein
the glass film covers the boundary and is disposed not to electrically connect the anode and the cathode.

17. The insulator according to claim 14, wherein
the glass film is disposed to cover a range from a surface of the cathode not in contact with the insulating material portion to a position between the cathode and the anode in the insulating material portion through the end portion.

18. The insulator according to claim 14, wherein
a thickness of a portion of the glass film covering the cathode is larger than a maximum thickness of a portion of the cathode covered with the glass film.

19. The insulator according to claim 14, wherein
a thickness of the glass film at the end portion is 20 μm or more.

20. The insulator according to claim 14, wherein
a contact angle of the glass film is less than 90°.

21. The insulator according to claim 14, wherein
the glass film is vanadium-containing glass.

22. The insulator according to claim 14, wherein
the insulating material portion is made of alumina.

23. A charged particle gun comprising:
the insulator according to claim 14.

24. A charged particle beam device comprising
the insulator according to claim 14.
